(19) United States
(12) Patent Application Publication
(10) Pub. No.: US 2025/0228061 A1
(43) Pub. Date: Jul. 10, 2025

(54) STACKED QUANTUM DOT SHORT-WAVELENGTH INFRARED SENSOR

(71) Applicant: SEMICONDUCTOR COMPONENTS INDUSTRIES, LLC, Scottsdale, AZ (US)

(72) Inventors: Vladimir KOROBOV, San Mateo, CA (US); Swarnal BORTHAKUR, Boise, ID (US)

(73) Assignee: SEMICONDUCTOR COMPONENTS INDUSTRIES, LLC, Scottsdale, AZ (US)

(21) Appl. No.: 19/091,534

(22) Filed: Mar. 26, 2025

Related U.S. Application Data
(63) Continuation of application No. PCT/US2023/075098, filed on Sep. 26, 2023.
(60) Provisional application No. 63/377,120, filed on Sep. 26, 2022.

(51) Int. Cl. H10K 39/32; G03F 7/00

(52) U.S. Cl. CPC H10K 39/32; G03F 7/0005

(57) ABSTRACT

An imager is configured for capturing short-wavelength infrared (SWIR) images. The imager includes an optical sensor die including a semiconductor substrate, at least one device fabricated in the semiconductor substrate, a layer of colloidal quantum dots (CQD) photodetectors disposed above of the semiconductor substrate, and an intermetal dielectric (IMD) layer disposed on a bottom surface of the semiconductor substrate. The IMD layer includes at least a metal level of a redistribution layer of the optical sensor die.

### RELATED APPLICATIONS

This application is a continuation of, and claims priority to, PCT Application No. PCT/US2023/075098 filed on Sep. 26, 2023, which claims priority to and the benefit of U.S. Provisional Application No. 63/377,120, filed Sep. 26, 2022, these applications are incorporated by reference herein in their entireties.

### TECHNICAL FIELD

This description relates to semiconductor optical sensors.

### BACKGROUND

An optical sensor is configured to convert a radiation intensity and a color spectrum into electrical signals. In some implementations, the optical sensor can include devices (e.g., photodiodes) for detecting light intensity. An optical sensor fabricated on a semiconductor die includes an optically active surface area (OASA) with an array of pixels responsible for converting a light and color spectrum into electrical signals. Photodiodes (p-n junctions) can detect visible radiation. Colloidal quantum dot (CQD) material that includes nanometer-sized dots (quantum dots) of compound semiconductor material (e.g., indium gallium arsenide (In GaAs), lead sulfide (PbS), etc.) can detect short-wavelength infrared radiation (SWIR). The OASA of an optical sensor may also include, for example, a micro lens array to focus incoming light into each pixel (thereby increasing the sensitivity of the image sensor) and/or include a color filter array (CFA).

### SUMMARY

In a general aspect, an imager is configured for capturing short-wavelength infrared (SWIR) images under front side illumination (FSI). The imager includes an optical sensor die including a semiconductor substrate. At least one device is fabricated in the semiconductor substrate. An intermetal dielectric (IMD) layer is disposed on a top surface of the semiconductor substrate. The IMD layer includes at least a metal level of a redistribution layer (RDL) of the optical sensor die. A layer of colloidal quantum dots (CQD) photodetectors disposed on the IMD layer.

In a further aspect, the imager includes a top electrode disposed on a top of the layer of CQD photodetectors, and an array of bottom electrodes disposed on a top surface of the IMD layer underneath the layer of CQD photodetectors. Each of the array of bottom electrodes corresponds to an optically-active pixel of the imager.

In yet another aspect, the optically-active pixel of the imager includes a capacitor with a pair of capacitor plates formed by one of the array of bottom electrodes and the top electrode. The CQD layer forms a capacitive material of the capacitor.

In a general aspect, an imager is configured is configured for capturing short-wavelength infrared (SWIR) images under back side illumination (BSI). The imager contains an optical sensor die including a semiconductor substrate. At least one device is fabricated in the semiconductor substrate. The imager further contains a layer of colloidal quantum dots (CQD) photodetectors disposed above a top surface of the semiconductor substrate, and an intermetal dielectric (IMD) layer disposed on a bottom surface of the semiconductor substrate. The IMD layer includes at least a metal level of a redistribution layer (RDL) of the optical sensor die.

In a further aspect, the imager includes a top electrode disposed on a top of the layer of CQD photodetectors, and an array of bottom electrodes disposed on the top surface of the semiconductor substrate underneath the layer of CQD photodetectors. Each of the array of bottom electrodes corresponds to an optically-active pixel of the imager.

In yet another aspect, the optically-active pixel of the imager includes a capacitor with a pair of capacitor plates formed by one of the array of bottom electrodes and the top electrode. The CQD layer forms a capacitive material of the capacitor.

In a general aspect, a method includes forming an optical sensor die including a semiconductor substrate. At least one device being fabricated in the semiconductor substrate. The method further includes disposing an intermetal dielectric (IMD) layer on a bottom surface of the semiconductor substrate with the IMD layer including at least a metal level of a redistribution layer (RDL) of the optical sensor die, and forming at least one bottom electrode on a top surface of the semiconductor substrate. The at least one bottom electrode corresponds to an optically-active pixel of a SWIR imager and is electrically connected to a metal level in the IMD layer. The method further includes disposing a layer of colloidal quantum dots (CQD) photodetectors on the top surface of the semiconductor substrate including over the at least one bottom electrode, and disposing a top electrode on a top of the layer of CQD photodetectors.

In a general aspect, a method includes forming an optical sensor die including a semiconductor substrate. At least one device is fabricated in the semiconductor substrate. The method further includes disposing an intermetal dielectric (IMD) layer on a top surface of the semiconductor substrate. The IMD layer includes at least a metal level of a redistribution layer (RDL) of the optical sensor die. The method further includes forming at least one bottom electrode on a top surface of the IMD layer. The at least one bottom electrode corresponds to an optically-active pixel of the SWIR imager, and is electrically connected to a metal level in the IMD layer. The method further includes disposing a layer of colloidal quantum dots (CQD) photodetectors on the IMD layer on the top surface of the IMD layer including over the at least one bottom electrode, and disposing a top electrode on a top of the layer of CQD photodetectors.

The details of one or more implementations are set forth in the accompanying drawings and the description below. Other features will be apparent from the description and drawings, and from the claims.

### BRIEF DESCRIPTION OF THE DRAWINGS

FIG. 1A schematically illustrates a SWIR image sensor die integrating use of colloidal quantum dots with silicon-based devices and circuits.

FIG. 1B schematically illustrates the SWIR image sensor die of FIG. 1A, further including an ASIC die bonded to a silicon device die.

FIG. 1C illustrates a cross-sectional view of an example colloidal quantum dot (CQD) sensor assembly configured for SWIR imaging under front side illumination (FSI) of the CQD sensor assembly.

FIG. 2A illustrates a cross-sectional view of the CQD sensor assembly of FIG. 1C in which a CQD layer is connected to a metal level.

FIG. 2B illustrates a cross-sectional view of the CQD sensor assembly of FIG. 1C in which the CQD layer is connected to a polysilicon gate of a transistor.

FIG. 2C illustrates a cross-sectional view of the CQD sensor assembly of FIG. 1C in which the CQD layer is connected to a source or drain of a transistor.

FIG. 3A illustrates, in a cross-sectional view, an example CQD sensor assembly 300 configured for SWIR imaging under back side illumination (BSI) of the CQD sensor assembly.

FIG. 3B illustrates, in a cross-sectional view, an example CQD sensor assembly for SWIR imaging under back side illumination (BSI). Each pixel of the CQD sensor assembly includes a high-k dielectric capacitor.

FIG. 4A illustrates a cross-sectional view of the CQD sensor assembly of FIG. 3A in which the CQD layer is connected to a metal level.

FIG. 4B illustrates a cross-sectional view of the CQD sensor assembly of FIG. 3A in which the CQD layer is connected to a polysilicon gate of a transistor.

FIG. 4C illustrates a cross-sectional view of the CQD sensor assembly of FIG. 3A in which the CQD layer is connected to a source or drain of a transistor.

FIG. 5A illustrates an example method for fabricating an optical sensor assembly (e.g., a SWIR imager) configured for imaging under front side illumination.

FIG. 5B illustrates an example method for fabricating an optical sensor assembly (e.g., a SWIR imager) including an ASIC die configured for imaging under front side illumination.

FIG. 6A illustrates an example method for fabricating an optical sensor assembly (e.g., a SWIR imager) configured for imaging under back side illumination.

FIG. 6B and FIG. 6C illustrate an example method for fabricating an optical sensor assembly (e.g., a SWIR imager) including an ASIC die configured for imaging under back side illumination.

In the drawings, which are not necessarily drawn to scale, like reference symbols or alpha numerals may indicate like and/or similar components (elements, structures, etc.) in different views. The drawings illustrate generally, by way of example, but not by way of limitation, various implementations discussed in the present disclosure. Reference symbols shown in one drawing may not be repeated for the same, and/or similar elements in related views. Reference symbols or alpha-numeral identifiers that are repeated in multiple drawings may not be specifically discussed with respect to each of those drawings but are provided for context between related views. Also, not all like elements in the drawings are specifically referenced with a reference symbol or alpha-numeral identifier when multiple instances of an element are illustrated.

### DETAILED DESCRIPTION

Colloidal quantum dot (CQD) material that includes nanometer-sized dots (quantum dots) of compound semiconductor material (e.g., indium gallium arsenide (InGaAs), lead sulfide (PbS), etc.) can react to short-wavelength infrared (SWIR) radiation (e.g., generate electrons in response to SWIR).

A SWIR image sensor described herein integrates the use of colloidal quantum dots made of compound semiconductor material with silicon-based devices and circuits that are used for signal gathering and image processing.

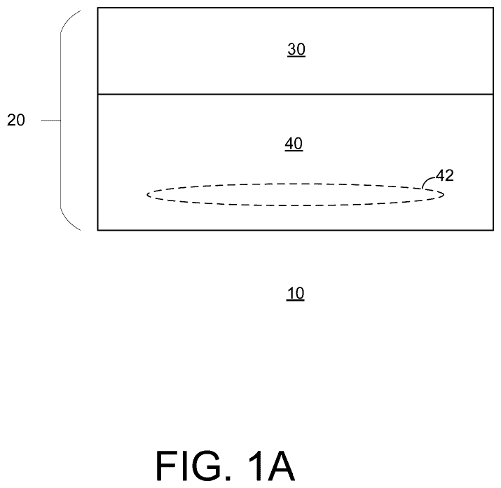

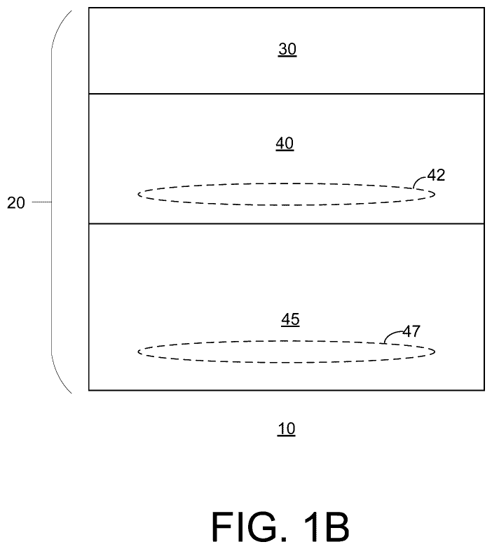

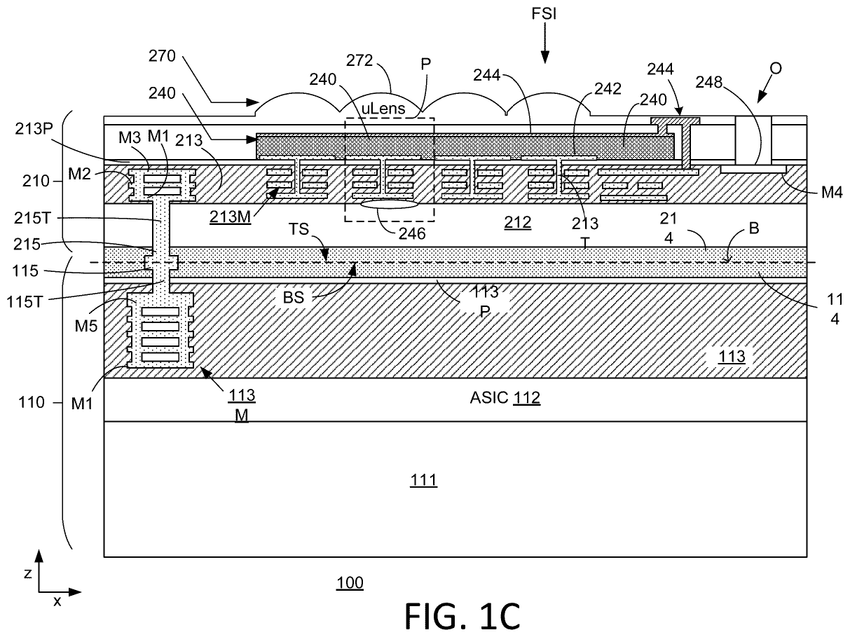

In example implementations, as shown schematically in FIG. 1A, a SWIR image sensor 10 may include a stack (e.g., stack 20) of a CQD material layer 30 and a silicon device die 40.

As shown in FIG. 1A, CQD material layer 30 is disposed on a top surface of a silicon device die 40 and may form a part of an optically active surface area (OASA) of the SWIR image sensor. The silicon device die may include circuits and devices (e.g., CMOS devices 42) for collecting the charge generated in the CQD material and amplifying and converting the charge into analog and digital electrical signals.

In some example implementations of SWIR image sensor 10, as shown in FIG. 1B, stack 20 further includes an application-specific integrated circuit (ASIC) die 45 disposed under, and bonded to, silicon device die 40. ASIC die 45 may include image signal processing (ISP) devices and circuits (e.g., circuits 47) fabricated in a silicon substrate for further processing of the electrical signals received from the silicon device die 40.

An optical sensor (e.g., a complementary metal-oxide semiconductor (CMOS) pixel sensor or a colloidal quantum dot (CQD) pixel sensor) fabricated on a semiconductor die includes an optically active surface area (OASA) with an array of pixel sensors (e.g., a x-y array of pixels) responsible for converting a light and color spectrum into electrical signals. Each pixel sensor in the array of pixels may include, for example, a photo diode or a photo transistor that senses and converts incident light into an electrical signal. The OASA of an optical sensor may also include, for example, a micro lens array (e.g., an x-y array of micro lenses) to focus incoming light into each pixel (thereby increasing the sensitivity of the optical sensor) and/or may include a color filter array (CFA) (e.g., a x-y array of filters) (i.e., a mosaic of tiny color filters coupled to the pixel sensors to capture color information).

In some implementations, the term pixel can refer to an individual pixel sensor device (e.g., a photo diode or a photo transistor), to the individual pixel sensor and an associated color filter, or collectively to the individual pixel sensor, the associated color filter, and an associated micro lens.

A short-wavelength infrared (SWIR) imager or sensor assembly is a type of an optical sensor configured for capturing images in light at wavelengths outside the visible range. An example SWIR imager may, for example, detect and capture images in the short-wavelength infrared (SWIR) region of the electromagnetic spectrum, which ranges from about 900 nm to 2500 nm. SWIR imagers have many applications in fields such as security, defense, agriculture, industrial automation, medical imaging, and automotive applications.

In example implementations, a SWIR imager may be a colloidal quantum dot (CQD) sensor based on a semiconductor material technology (e.g., silicon material technology). When a semiconductor material absorbs light, it releases an electron from a chemical bond, and that electron is free to roam through the semiconductor material. The same process happens in a quantum dot (QD) material in which the quantum dots may be only a few nanometers in diameter. However, unlike in bulk semiconductor material, the released electron cannot roam freely. The released electron gets squeezed (i.e., is quantum confined) by the edges of the quantum dot, because the quantum dot is of limited finite size (e.g., only a few nanometers in diameter). A useful property of a quantum dot for imaging is that the light absorbed by the quantum dot is tunable, i.e., the color can be continuously adjusted to almost any wavelength in the visible and infrared spectrum simply by choosing the right material, the right dot (particle) size, and the right bias voltages. In a SWIR imager based on colloidal quantum dots, each pixel can include a CQD capacitor formed by a pair of capacitor plates (e.g., a bottom metal electrode and a transparent top electrode) and the CQD layer as the capacitive material between the pair of plates. The charge generated by SWIR radiation incident on the capacitive material can be held by, and read from the capacitors, pixel-by-pixel, as a measure of the incident SWIR radiation. In some example implementations, a layer of high-k dielectric material may be disposed in each pixel under the bottom metal electrode. The high-k dielectric material may provide the capacitive material for a high value capacitor formed between the bottom electrode and the semiconductor material (e.g., silicon) of the pixel.

Newer industrial and consumer applications (e.g., automotive applications such as advanced driver assistance systems (ADAS) and autonomous driving (AD) systems) need other circuitry (e.g., image signal processor (ISP) or an ASIC) to be included in the same IC package as the optical sensor die for improved imaging performance. The other circuitry (e.g., ISP or the ASIC die) can be, for example, coupled to, or combined with, the optical sensor die in a package.

The devices of an optical sensor may be fabricated in a semiconductor die (optical sensor die) (e.g., by wafer-level processing steps) and coupled to circuitry (e.g., ASIC including a driver circuit, A/D convertor, etc.). The ASIC circuits may be fabricated on a same semiconductor die as the devices for detecting light intensity, or on a separate ASIC die coupled to the optical sensor die.

In some implementations, an optical sensor and the associated ASIC circuits can produce an electrical output. The raw image (RAW) data generated by the optical sensor may be, for example, in the form of zeroes and ones for each pixel of the optical sensor array. Furthermore, an image signal processor (ISP) can be a dedicated processor that converts the RAW data generated by the optical sensor into a workable image output through various signal conditioning processes. These various signal conditioning processes may include, for example, one or more of: noise reduction, lens shading correction, gamma correction, auto exposure, or auto white balance, etc.

This disclosure describes an imager (sensor assembly) that includes a quantum dot short-wavelength infrared sensor die as an optical sensor die. The quantum dot short-wavelength infrared sensor die is fabricated as a CQD die including a layer of colloidal quantum dots disposed on a top surface of a silicon device die.

In some example implementations, the silicon device die is coupled to an ASIC die in the imager (sensor assembly).

In example implementations, the CQD die (sensor die) may be directly stacked above (in other words, placed above), bonded, and/or electrically connected to the ASIC die.

In some example implementations, the CQD die may be placed face-to-face with the ASIC die and bonded directly to the ASIC die. In example implementations, fabrication of the CQD sensor assembly (including the CQD die, the ASIC die, and the bonding of the two) may involve wafer-level processing steps. The bonded surfaces of the CQD die and the ASIC die may include surface regions of heterogenous materials (e.g., conductive material such as copper, passivation material such as oxides or other dielectrics, and semiconductor material such as silicon, etc.). Bonding of the CQD die and the ASIC die may involve techniques (e.g., hybrid bonding) for stacking and electrically connecting the dies together. The hybrid bonding may involve, for example, introducing cooper pads disposed in dielectric material layers on the surfaces of the two dies, stacking the two dies face-to-face, aligning the copper pads disposed on opposing surfaces of dies, and bonding or fusing the copper pads together (in addition to bonding the remainder of the opposing surfaces together). As a result, the two dies in the assembly may be electrically connected using small copper-to-copper connections.

The copper pads on the surfaces of the dies (e.g., the ASIC die and the CQD die) may be connected to metal levels of the redistribution layers of respective dies using, for example, metal-filled through-silicon vias (TSVs).

In some example implementations, the CQD sensor assembly described herein may be configured for SWIR imaging under front side illumination (FSI) of the CQD sensor assembly. The CQD sensor (or sensor assembly) may be referred to as being front side illuminated, because incident light passes through a portion or layer of the sensor assembly that, for example, includes wiring (e.g., the metal levels of a redistribution layer or other circuits) before passing through to the silicon layer that may include pixel devices (e.g., devices such as photodiodes) in the CQD sensor assembly. The bottom side of the front-illuminated CQD die may be bonded (e.g., hybrid bonded) to the top side of the ASIC die with electrical connections between the two dies.

In some other example implementations, the CQD sensor assembly described herein may be configured for SWIR imaging under back side illumination (BSI) of the CQD sensor assembly. A back-illuminated CQD sensor assembly contains the same elements as the front-illuminated CQD sensor assembly, however, the layer including the wiring (i.e., the portion of the sensor including the metal levels of the redistribution layer) is placed behind the silicon layer so that light incident on the CQD sensor assembly illuminates the silicon layer first before passing through to the layer including the wiring (e.g., the metal levels of the redistribution layer or other circuits).

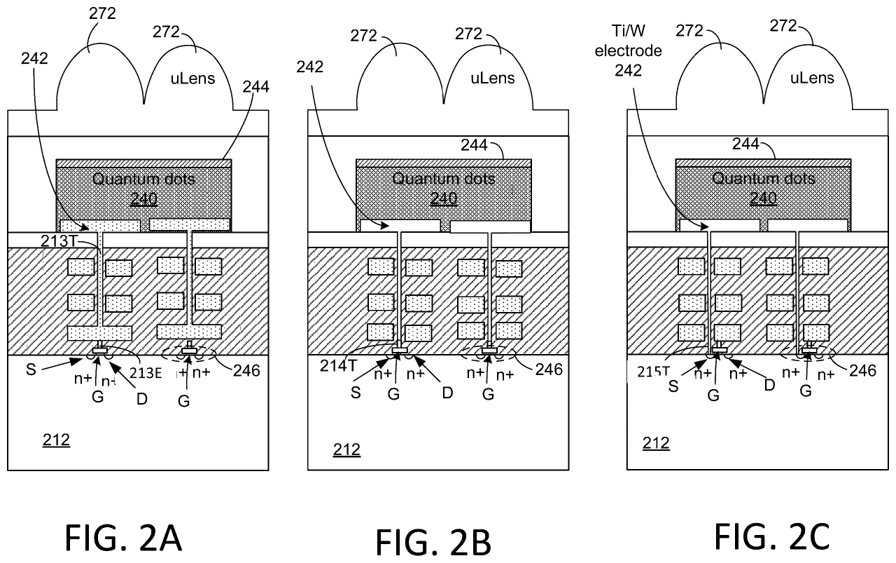

FIGS. 1C, 2A, 2B, and 2C show cross-sectional views of an example CQD sensor assembly 100 (e.g., imager) configured for SWIR imaging under front side illumination (FSI) of the CQD sensor assembly. In FIG. 1C, the front side illumination is indicated, for example, by an arrow that is marked FSI at the top of the figure.

As shown in FIG. 1C, in example implementations, CQD sensor assembly 100 includes an ASIC die 110 placed underneath and bonded to a quantum dot-based short-wavelength infrared sensor die (e.g., CQD die 210).

ASIC die 110 may include a layer (e.g., ASIC layer 112) fabricated on or in a semiconductor substrate (e.g., silicon substrate 111). ASIC layer 112 may include devices and circuits (e.g., diodes and transistors) (not shown) for image signal processing. ASIC die 110 may further include an intermetal dielectric layer (IMD layer 113) and a passivation layer (e.g., layer 113P) disposed on ASIC layer 112. IMD layer 113 may include metal levels 113M (e.g., metal level M1 . . . , M5) of a redistribution layer for distributing electrical signals to and from the devices and circuits in ASIC die 110.

An oxide layer (e.g., oxide layer 114) may be disposed on IMD layer 113. A top surface TS of oxide layer 114 may form a bonding surface for bonding CQD die 210 across, for example, a bond line indicated as dashed line B in FIG. 1C.

In example implementations, a metal pad (e.g., copper pad 115) may be embedded in oxide layer 114 at about top surface TS. The top surface TS of oxide layer 114 including copper pad 115 may be planarized (e.g., by chemical mechanical polishing (CMP)) to prepare a bonding surface for bonding CQD die 210 across, for example, the bond line indicated as dashed line B in FIG. 1C.

The metal pad (e.g., copper pad 115) may be electrically connected by a through-substrate via (e.g., TSV 115T) to the metal levels 113M (e.g., metal level M1 . . . , M5) of the redistribution layer for distributing electrical signals to and from the devices and circuits in ASIC die 110. In example implementations, the metal levels 113M (e.g., metal level M1 . . . , M5) of the redistribution layer in ASIC die 110 may be made of a metal or a metal alloy (e.g., copper, aluminum, etc.).

In the CQD sensor assembly 100 shown in FIG. 1C, CQD die 210 may include a layer of colloidal quantum dot photodetectors (e.g., CQD layer 240), disposed on an intermetal dielectric layer (IMD layer 213). IMD layer may be disposed on a semiconductor substrate (e.g., silicon substrate 212). A passivation layer (e.g., layer 213P) may be disposed between CQD layer 240 and IMD layer 213.

CQD layer 240 may include, for example, an optically sensitive layer of colloidal semiconductor nanocrystals dispersed in a film (e.g., as a spin-on organic fluid colloid) disposed on IMD layer 213/layer 213P. The nanocrystals may include, for example, at least one of PbS, InAs, InP, PbSe, CdS, CdSe, InₓGa₁₋ₓAs, CdHgTe, ZnSe (PbS), ZnS (CdSe), ZnSe (CdS), PbO (PbS), and PbSO₄(PbS) or other semiconductor.

CQD layer 240 may extend across an array of pixels (e.g., pixel P). FIG. 1C shows, for example, an example pixel (e.g., pixel P) as a rectangle marked in dashed line. In example implementations, the number of pixels in an imager may be, for example, in the hundreds of thousands or even in the millions.

As shown in FIG. 1C, pixel P includes a top electrode (e.g., electrode 244) disposed on CQD layer 240 and a bottom electrode (e.g., electrode 242) disposed underneath CQD layer 240 in each pixel P. All pixels P may share a common top electrode (e.g., electrode 244), while each pixel P may have its own individual bottom electrode (e.g., electrode 242). In example implementations, electrode 244 and electrode 242 may be, for example, made of a metal and/or an at least partially transparent material (e.g., indium tin oxide, indium oxide, tungsten oxide, aluminum, gold, platinum, silver, magnesium, copper, and combinations and layer structures thereof). In example implementations, the top electrode may be, for example, an indium tin oxide (ITO) material doped with ZnO and Al. In example implementations, the electrode 242 may be, for example, a patterned layer of metals including, for example, at least one of copper, tantalum, titanium, or tungsten.

In CQD die 210, the intermetal dielectric layer (IMD layer 213) may include metal levels 213M (e.g., metal level M1 . . . , M3) of a redistribution layer for distributing electrical signals (e.g., the output of the quantum dots) in each pixel P to and from pixel devices (e.g., diodes, transistors, amplifiers, etc.) (e.g., device 246) that may be fabricated, for example, in, or on, silicon substrate 212, and coupled to the quantum dots in CQD layer 240. The pixel devices (e.g., device 246) may be CMOS devices. In some example implementations, electrode 242 may be connected to a metal level (e.g., metal level M1) in metal levels 213M, for example, a through a metal-filled via (e.g., via 213T) passing through IMD layer 213. In example implementations, the metal levels (e.g., metal level M1 . . . , M3) of the redistribution layer in CQD die 210 may be made of a metal or a metal alloy (e.g., copper, or aluminum).

In CQD die 210, the silicon substrate (e.g., silicon substrate 212) may be a thinned silicon substrate. An oxide layer (e.g., oxide layer 214 may be disposed on a back side of silicon substrate 212. A bottom surface BS of oxide layer 214 may form a bonding surface for bonding CQD die 210 to ASIC die 110 across, for example, the bond line indicated as dashed line B in FIG. 1C.

In example implementations, a metal pad (e.g., copper pad 215) may be embedded in oxide layer 214 at about bottom surface BS or about the bond line B. The bottom surface BS of oxide layer 214 including copper pad 215 may planarized (e.g., by chemical mechanical polishing (CMP)) to prepare a bonding surface for bonding CQD die 210 to ASIC die 110 across, for example, the bond line indicated as dashed line B in FIG. 1C.

The metal pad (e.g., copper pad 215) may be electrically connected by a metal-filled through substrate via (e.g., via 215T (e.g., TSV)) to the metal levels 213M (e.g., metal level M1 . . . , M3) of the redistribution layer for distributing electrical signals to and from the devices and circuits in CQD die 210.

In example implementations, for bonding (i.e., hybrid bonding) ASIC die 110 and CQD die 210 together, surface TS of oxide layer 114 of ASIC die 110 and surface BS of oxide layer 214 of CQD die 210 are positioned against each other face-to-face and bonded together in a hybrid bonding process (in other words, in an oxide-to oxide and metal-to metal bonding process).

In example implementations, the metal pad (e.g., copper pad 115) in oxide layer 114 and the metal pad (e.g., copper pad 215) in oxide layer 214 may be aligned and joined together in the hybrid bonding process. The hybrid bonding process may involve low temperature (e.g., 200° C. to 250° C.) treatments of the bonded assembly, which can result in copper interdiffusion to join copper pad 115 and the copper pad 215 together. The joining of copper pad 115 and the copper pad 215 may electrically connect the redistribution layers (e.g., metal level M1 . . . , M5, and metal level M1 . . . , M3) of the two dies exchanging electrical signals between ASIC die 110 and CQD die 210.

The metal levels (e.g., metal level M1 . . . , M3 and metal level M1 . . . , M3) in the two dies may be made of copper. In an example implementation, the redistribution layer in CQD die 210 may include a further metal level (e.g., metal level M4) disposed in IMD layer 213. Metal level M4 may include an aluminum pad (e.g., aluminum pad 248) that is accessible through an opening O at a top of CQD die 210, for example, for wire bonding external wire connections to the die.

In example implementation, CQD die 210 may include a micro lens array (e.g., array 270 of micro lens 272) disposed on a front surface FS of the die to focus incoming light into each pixel P.

In example implementations, each pixel P may be associated with a pixel device (e.g., device 246) that may be fabricated in, for example, silicon substrate 212. In example implementations, device 246 may be a MOSFET device fabricated in or on a surface of silicon substrate 212. As shown in FIGS. 2A through FIG. 2C, device 246 may include a polysilicon gate (e.g., polysilicon gate G) disposed on the surface of silicon substrate 212 and heavily doped source and drain regions (e.g., source S, drain D) disposed in or on the surface of silicon substrate 212.

In some example implementations, as shown in FIG. 2A, the bottom electrode (e.g., electrode 242) disposed underneath CQD layer 240 in each pixel P may be connected to metal level M1 through a metal-filled via 213T (e.g., copper-filled via), and further connected to the polysilicon gate (e.g., polysilicon gate G) disposed on the surface of silicon substrate 212 through an extension (e.g., via extension 213E) of the metal-filled via 213T. Electrode 242 may be composed of, for example, tantalum and or copper.

In some example implementations, as shown in FIG. 2B, the bottom electrode (e.g., electrode 242) disposed underneath CQD layer 240 in each pixel P may be connected to only the polysilicon gate (e.g., polysilicon gate G) disposed on the surface of silicon substrate 212 through metal-filled via 214T. Electrode 242 may be composed of, for example, titanium and tungsten.

In some example implementations, as shown in FIG. 2C, the bottom electrode (e.g., electrode 242) disposed underneath CQD layer 240 in each pixel P may be connected to only the heavily doped source and drain regions (e.g., source S) disposed in or on the surface of silicon substrate 212 through metal-filled via 215T. Electrode 242 may be composed of, for example, titanium and tungsten.

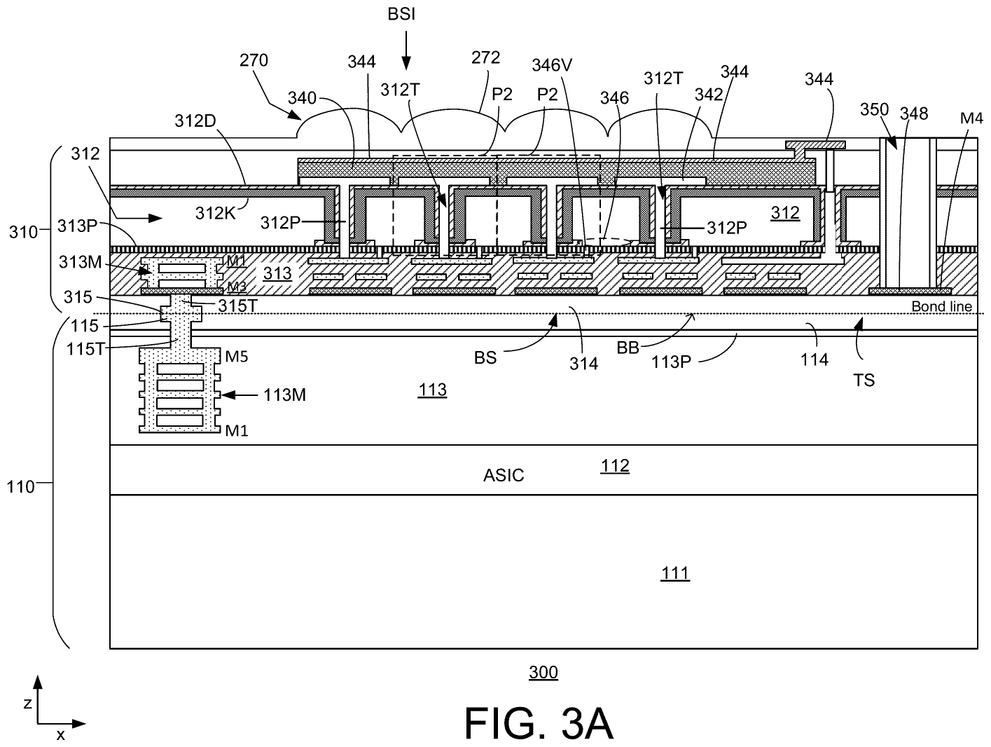

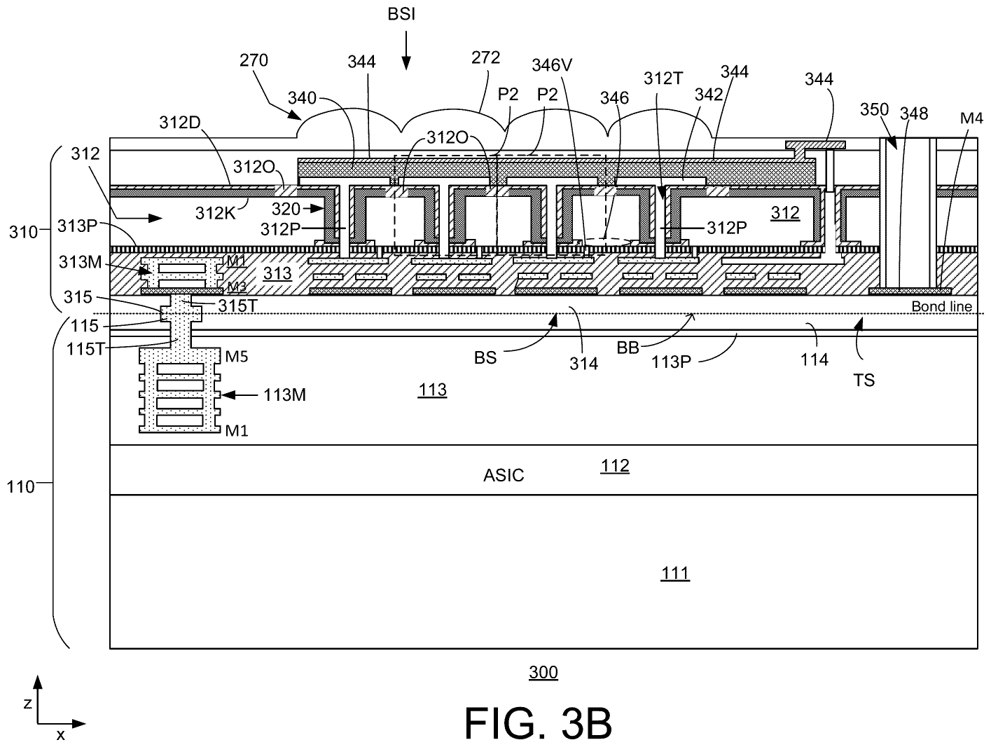

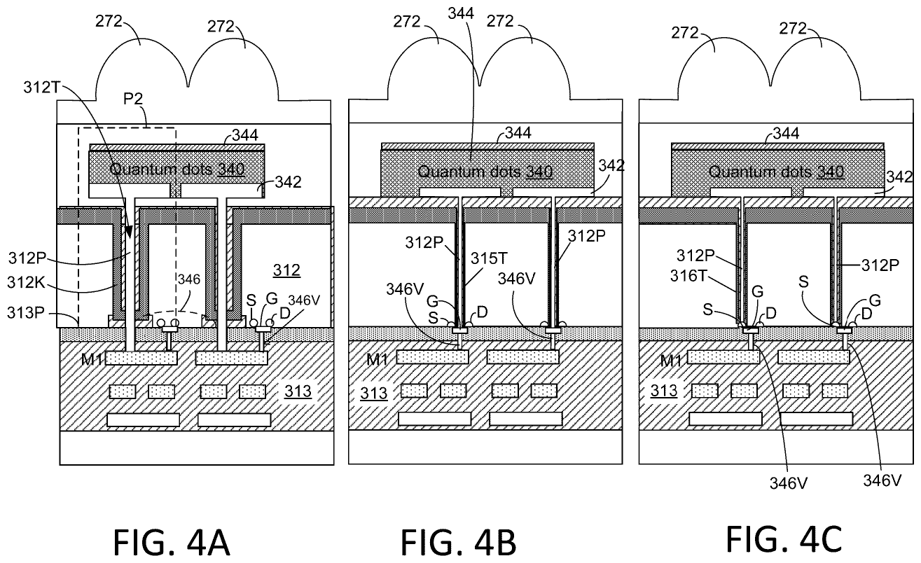

FIG. 3A, FIG. 3B, and FIG. 4A through FIG. 4C show, in cross-sectional views, an example CQD sensor assembly 300 (imager) configured for SWIR imaging under back side illumination (BSI) of the CQD sensor assembly. FIG. 3A and FIG. 3B, the back side illumination is indicated by, for example, an arrow that is marked BSI at the top of the figure.

As shown in FIG. 3A, in example implementations, CQD sensor assembly 300 includes a CQD die 310 that includes an optically active (SWIR active) CQD layer 340 disposed on a top surface of a thinned silicon substrate (e.g., silicon substrate 312). An ASIC die 110 is placed underneath and bonded to the quantum dot-based short-wavelength infrared sensor die (e.g., CQD die 310).

In CQD sensor assembly 300 shown in FIG. 3A, CQD die 310 may include a layer of a colloidal quantum dot photodetectors (e.g., CQD layer 340) disposed on a top surface of a thinned silicon substrate (e.g., silicon substrate 312). An IMD layer 313 may be disposed underneath the semiconductor substrate (e.g., silicon substrate 312). A passivation layer (e.g., layer 313P) may be disposed between substrate 312 and IMD layer 313.

In example implementations, a top surface (and other exposed surfaces) of silicon substrate 312 may be coated with passivating dielectrics including, for example, a layer of high-k dielectrics (e.g., a layer 312K) and a layer of silicon oxide (e.g., a layer 312D) or other dielectrics. Layer 312K may be, for example, a high-k dielectric including Al₂O₃/HfO₂/Ta₂O₅.

CQD layer 340 may include, for example, colloidal semiconductor nanocrystals dispersed in a film (e.g., as a spin-on organic fluid colloid) on substrate 312. The semiconductor nanocrystals (quantum dot photodetectors) may include, for example, at least one of PbS, InAs, InP, PbSe, CdS, CdSe, InₓGa₁₋ₓAs, CdHgTe, ZnSe (PbS), ZnS (CdSe), ZnSe (CdS), PbO (PbS), and PbSO4 (PbS) nanocrystals or other semiconductor quantum dots.

CQD layer 340 may extend across an array of pixels (e.g., pixel P2). FIG. 3A shows, for example, a pair of adjacent pixels (e.g., pixel P2) as a rectangles marked in dashed line. In example implementations, an imager may include, for example, hundreds of thousands, or even millions, of pixels.

As shown in FIG. 3A, pixel P2 includes a top electrode (e.g., electrode 344) disposed on CQD layer 340 and a bottom electrode (e.g., electrode 342) disposed underneath CQD layer 340 in each pixel P2. All pixels P2 may share a common top electrode (e.g., electrode 344), while each pixel P2 may have its own individual bottom electrode (e.g., electrode 342). In example implementations, electrode 344 and bottom electrode 342 may be, for example, made of a metal and/or an at least partially transparent material (e.g., indium tin oxide, indium oxide, tungsten oxide, aluminum, gold, platinum, silver, magnesium, copper, and combinations and layer structures thereof). In an example implementation, the top electrode may be, for example, an indium tin oxide (ITO) material doped with ZnO and Al. In example implementations, bottom electrode 342 may be, for example, a patterned layer of metal including, for example, one or more of copper, tantalum, titanium, or tungsten.

In example implementations, the top electrode (e.g., electrode 344) and the bottom electrodes (e.g., electrodes 342) in each pixel P2 may be connected to a metal level (e.g., metal level M1) in an intermetal dielectric layer (e.g., IMD layer 313) disposed underneath silicon substrate 312. The connection may be made by, for example, metal plug 312P disposed in a through-silicon via (e.g., TSV 312T). TSV 312T may be filled or lined with oxide (e.g., layer 312D) for passivation.

FIG. 3B illustrates, in a cross-sectional view, an example CQD sensor assembly 300-1 for SWIR imaging under back side illumination (BSI). Each pixel of the CQD sensor assembly 300-1 includes a high-k dielectric capacitor.

As shown in FIG. 3B, a layer of high-k dielectric (e.g., layer 312K) may be disposed on the top surface of silicon substrate 312 and on sidewalls of the through silicon vias (e.g., TSV 312T) that may define the vertical boundaries of the opening in each pixel for receiving metal plug 312P. Layer 312k in a pixel p2 may be isolated from layer 312k in a neighboring pixel p2 by a silicon oxide segment (e.g., oxide segment 312O). In each pixel, a value capacitor is formed by the high-k dielectric (e.g., layer 312K) material disposed between the bottom electrode (e.g., electrode 342) and the silicon substrate (e.g., silicon substrate 312). The pixels may be individually connected by the Ta/TiN/W contacts (e.g., electrode 342). Each pixel is isolated creating individual high value capacitors with the high-k dielectric material (e.g., Al2)3/HfO2/Ta2O5).

In example implementations, each pixel contact may be made with tantalum, titanium nitride and tungsten (Ta/TiN/W) contacts (e.g., electrode 342). Each pixel contact may be isolated, as shown in FIG. 3B, creating an in-pixel trench capacitor 320 with the high-k dielectric layer (e.g., layer 312K) that, for example, includes aluminum oxide, hafnium oxide, and tantalum oxide (Al₂O₃/HfO₂/Ta₂O₅).

In CQD die 310, the intermetal dielectric layer (IMD layer 313) may include metal levels 313M (e.g., metal level M1 . . . , M3) of a redistribution layer for distributing electrical signals (e.g., the output of the quantum dots) in each pixel P2 to and from pixel devices (e.g., diodes, transistors, amplifiers, etc.) (e.g., pixel device 346) that may be fabricated, for example, in or on silicon substrate 312, and coupled to the quantum dots. In some example implementations, pixel device 346 may be connected to metal level M1, for example, a through a via (e.g., via 346V) passing through IMD layer 313. In example implementations, the metal levels (e.g., metal level M1 . . . , M3) of the redistribution layer in CQD die 310 may be made of a metal or a metal alloy (e.g., copper, or aluminum).

In example implementations, an oxide layer (e.g., oxide layer 314) may be disposed on a back side of IMD layer 313 that is disposed underneath silicon substrate 312. A bottom surface BS of oxide layer 314 may form a bonding surface for bonding CQD die 310 to ASIC die 110 across, for example, a bond line indicated as dashed line BB in FIG. 3A.

As described with reference to CQD sensor assembly 100 (shown in FIG. 1C), ASIC die 110 includes an intermetal dielectric layer (IMD layer 113) and a passivation layer (e.g., layer 113P) disposed on ASIC layer 112. IMD layer 313 includes metal levels (e.g., metal level M1 . . . , M5) of a redistribution layer for distributing electrical signals to and from the devices and circuits in ASIC die 110.

An oxide layer (e.g., oxide layer 114) may be disposed on IMD layer 113. A top surface TS of oxide layer 114 may form a bonding surface for bonding CQD die 310 across, for example, a bond line indicated as dashed line BB in FIG. 3A.

The top surface TS of oxide layer 114 including a copper pad 115 may be planarized (e.g., by chemical mechanical polishing (CMP)) to prepare a bonding surface for bonding CQD die 310 across, for example, bond line indicated as dashed line BB in FIG. 3A.

The metal pad (e.g., copper pad 115) may be electrically connected by a metal-filled through-substrate via (e.g., TSV 115T) to the metal levels 113M (e.g., metal level M1 . . . , M5) of the redistribution layer in ASIC die 110 for distributing electrical signals to and from the devices and circuits in ASIC die 110. In example implementations, the metal levels (e.g., metal level M1 . . . , M5) of the redistribution layer in ASIC die 110 may be made of a metal or a metal alloy (e.g., copper).

In the CQD sensor assembly 300 shown in FIG. 3A, CQD die 310 may include a layer of a colloidal quantum dot photodetectors (e.g., CQD layer 340) disposed on a semiconductor substrate (e.g., silicon substrate 312). An intermetal dielectric layer (e.g., IMD layer 313) is disposed underneath (in other words, on a back side of) silicon substrate 312. A passivation layer (e.g., layer 313P) may be disposed between silicon substrate 312 and IMD layer 313.

In CQD die 310, the intermetal dielectric layer (IMD layer 313) may include various metal levels (e.g., metal level M1 . . . , M3) of a redistribution layer for distributing electrical signals (e.g., the output of the quantum dots) in each pixel P2 to and from pixel devices (e.g., diodes, transistors, amplifiers, etc.) (e.g., pixel device 346) that may be fabricated, for example, in, or on, silicon substrate 312, and coupled to the quantum dots. In some example implementations, bottom electrode 342 may be connected to metal level M1, for example, a through via (e.g., TSV 312T (e.g., via)) passing through IMD layer 313. In example implementations, the metal levels (e.g., metal level M1 . . . , M3) of the redistribution layer in CQD die 310 may be made of a metal or a metal alloy (e.g., copper, or aluminum). In the example shown in FIG. 3A, metal level M1 (and M2) may be, for example, made of copper, and metal level M3 may be, for example, made of aluminum.

An oxide layer (e.g., oxide layer 314) may be disposed on a back side of IMD layer 313. A bottom surface BS of oxide layer 314 may form a bonding surface for bonding CQD die 310 to ASIC die 110 across, for example, a bond line indicated as dashed line BB in FIG. 3A.

In example implementations, a metal pad (e.g., copper pad 315) may be embedded in oxide layer 314 at about bottom surface BS or the bond line BB. The bottom surface BS of oxide layer 314 including copper pad 315 may planarized (e.g., by chemical mechanical polishing (CMP)) to prepare a bonding surface for bonding CQD die 310 across, for example, the bond line indicated as dashed line BB in FIG. 3A.

The metal pad (e.g., copper pad 315) may be electrically connected by a through via (e.g., via 315T) passing through IMD layer 313 to a metal level (e.g., metal level M1 . . . , M3) of the redistribution layer for distributing electrical signals to and from the devices and circuits in CQD die 310.

In example implementations, for bonding (e.g., hybrid bonding) ASIC die 110 and CQD die 310 together, surface TS of oxide layer 114 of ASIC die 110 and surface BS of oxide layer 314 of CQD die 310 are positioned against each other and bonded together in a hybrid bonding process (in other words, in a bonding process including both oxide-to-oxide bonding and metal-to-metal bonding).

In example implementations, the metal pad (e.g., copper pad 115) in oxide layer 114 and the metal pad (e.g., copper pad 315) in oxide layer 314 may be aligned and joined together in the hybrid bonding process. The hybrid bonding process may involve low temperature (e.g., 200° C. to 250° C.) treatments of the bonded assembly which can result in copper interdiffusion to join copper pad 115 and the copper pad 315. The joining of copper pad 115 and the copper pad 215 may electrically connect the redistribution layers (e.g., metal level M1 . . . , M5, and metal level M1 . . . , M3) of the two dies. This may enable exchange of electrical signals between ASIC die 110 and CQD die 310.

In some example implementations, the redistribution layer in CQD die 310 may include a further metal level (e.g., metal level M4) disposed in IMD layer 313. Metal level M4 may be a part or an extension of metal level 3. Metal level 4 may include an aluminum pad (e.g., aluminum pad 348) that is accessible through an opening 350 at a top of CQD die 310, for example, for wire bonding external wire connections to the die.

In example implementations, CQD die 310 may further include an array of micro lenses (e.g., array 270 of micro lens 272) disposed on a top surface of the die to focus incoming light (e.g., back side illumination BSI) into each pixel P2.

In example implementations, each pixel P2 in CQD die 310 may be associated with a pixel device (e.g., pixel device 346) that may be fabricated, for example, in or on silicon substrate 312. In example implementations, pixel device 346 may be a MOSFET device fabricated in, or on, a surface of silicon substrate 312. As shown in FIG. 4A through FIG. 4C, pixel device 346 may include a polysilicon gate (e.g., polysilicon gate G) disposed on the surface of silicon substrate 312 and a heavily doped source region (e.g., source S) and a heavily doped drain region (e.g., drain D) of a transistor fabricated in or on the surface of silicon substrate 312.

In some example implementations, as shown in FIG. 3A and FIG. 4A, the bottom electrode (e.g., electrode 342) disposed underneath CQD layer 340 in each pixel P2 may be connected to metal level M1 by metal plug 312P disposed in a through-silicon via (e.g., TSV 312T) extending through silicon substrate 312. Furthermore, metal level M1 may be independently connected to the polysilicon G of pixel device 346 by a metal-filled via (e.g., via 346V) passing through IMD layer 313.

Electrode 342 may be composed of, for example, tantalum and or copper.

In some example implementations, as shown in FIG. 4B, the bottom electrode (e.g., electrode 342) disposed underneath CQD layer 340 in each pixel P2 may be connected directly to the polysilicon gate G of pixel device 346 by metal plug 312P disposed in a through-silicon via (e.g., via 315T (e.g., TSV)) extending through silicon substrate 312. Furthermore, metal level M1 may be independently connected to the polysilicon G of pixel device 346 by a metal-filled via (e.g., via 346V) passing through IMD layer 313.

In some example implementations, as shown in FIG. 4C, the bottom electrode (e.g., electrode 342) disposed underneath CQD layer 340 in each pixel P2 may be connected to directly to a heavily doped source (e.g., source s) of pixel device 346 by metal plug 312P disposed in through-silicon via (e.g., TSV 316T) extending through silicon substrate 312. Furthermore, metal level M1 may be independently connected to the polysilicon gate G of pixel device 346 by a metal-filled via (e.g., via 346V) passing through IMD layer 313.

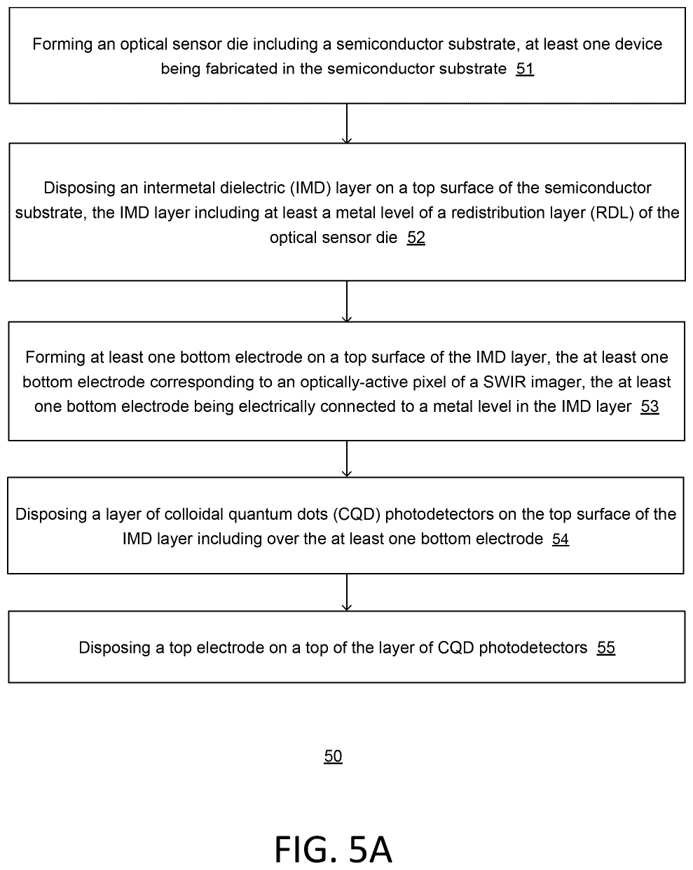

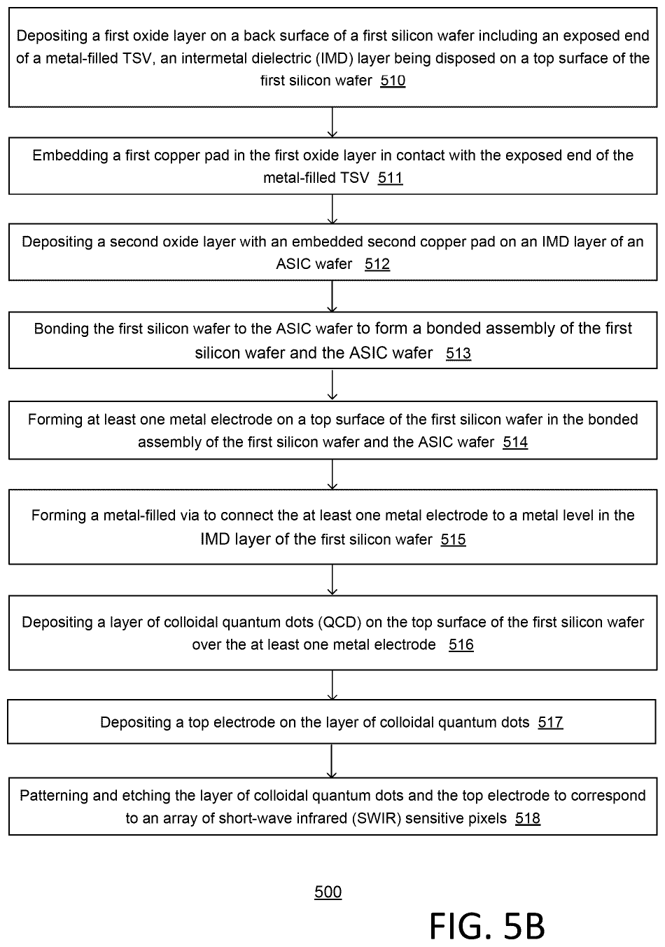

FIG. 5A shows an example method 50 for fabricating an example CQD imager (sensor assembly) configured for SWIR imaging under front side illumination (FSI) of the CQD sensor assembly.

Method 50 includes forming an optical sensor die including a semiconductor substrate (51). At least one device is fabricated in the semiconductor substrate. The at least one device may be, for example, a MOSFET device (e.g., an amplifier). Method 50 further includes disposing an intermetal dielectric (IMD) layer on the semiconductor substrate (52). The IMD layer includes at least a metal level of a redistribution layer (RDL) of the optical sensor die. Method 50 further includes forming at least one bottom electrode on the IMD layer (53). The at least one bottom electrode corresponds to an optically-active pixel of a SWIR imager. The least one bottom electrode is electrically connected to a metal level in the IMD layer. Method 50 further includes disposing a layer of colloidal quantum dots (CQD) photodetectors on the IMD layer including over the at least one bottom electrode (54), and disposing a top electrode on the layer of CQD photodetectors (55).

In example implementations, each of the array of bottom electrodes may correspond to an optically-active pixel of a SWIR imager.

In example implementations, method 50 may include patterning and etching the layer of colloidal quantum dots and the top electrode to correspond to an array of short-wavelength infrared (SWIR) sensitive pixels.

In example implementations, method 50 may further include depositing an array of micro lenses on top of the semiconductor substrate. Each micro lens may be configured to funnel incident light into a SWIR-sensitive pixel.

In example implementations, the semiconductor substrate may be bonded to, and electrically connected to, an ASIC die. Bonding the semiconductor substrate to the ASIC die may involve depositing an oxide layer on the back surface of the semiconductor substrate and an oxide layer on an IMD layer of the ASIC die. The two oxide layers may include respective copper pads that are electrically connected to metal levels in respective redistribution layers of the optical sensor die and the ASIC die. In a bonding process, the oxide layer on the semiconductor substrate is placed in face-to-face contact with the oxide layer on the IMD layer of the ASIC die. The copper pads in the two oxide layers are mutually aligned and fused with each other in a hybrid bonding process (including, e.g., oxide-oxide and metal-metal bonding).

FIG. 5B shows an example method 500 for fabricating an example CQD imager (sensor assembly) including an ASIC die and a silicon device die configured for SWIR imaging under front side illumination (FSI) of the CQD sensor assembly.

Method 500 may involve using a first silicon wafer (a silicon device wafer) as a precursor silicon substrate for fabricating a passivated CQD die (in other words, the first silicon wafer is a precursor silicon substrate, which may later be provided with a layer of colloidal quantum dot photodetectors (e.g., CQD layer 240) to form an optically active CQD SWIR imager).

The first silicon wafer may include an intermetal dielectric (IMD) layer disposed on a top surface of a semiconductor layer. The IMD layer may have one of more metal levels (e.g., M1, M2, M3, M4, etc.) of a redistribution layer. Furthermore, the first silicon wafer may include a metal-filled through silicon via (TSV) connected to a metal level of the redistribution layer and extending at least partially through a thickness of the silicon substrate. The first silicon wafer may undergo back grinding to expose an end of the metal-filled TSV on the back surface of the first silicon wafer.

In some example implementations, the metal-filled TSV connected to the metal level of the redistribution layer may be formed by back grinding the first silicon wafer to a target thickness, etching the TSV to expose the metal level of the redistribution layer, and back-filling the TSV with metal.

Method 500 may include depositing a first oxide layer on a back surface of the first silicon wafer including an exposed end of the metal-filled TSV (510), and embedding a first copper pad in the first oxide layer in contact with the exposed end of the metal-filled TSV (511). In example implementations, method 500 may further include planarizing (e.g., by CMP) the first oxide layer including the first copper pad.

Further steps in method 500 may relate to bonding a second silicon wafer to the first silicon wafer. The second silicon wafer (“ASIC” wafer) may include a layer of circuits and devices (e.g., application-specific integrated circuits (ASIC)) for signal processing (e.g., image signal processing). An IMD layer may be disposed on a top surface of the ASIC wafer. The IMD layer may have one of more metal levels (e.g., M1, M2, M3, M4, M5, etc.) of a redistribution layer for making electrical connections to the layer of circuits and devices in the ASIC wafer.

Method 500 may further include depositing a second oxide layer with an embedded second copper pad on an IMD layer of an ASIC wafer (512). The second oxide layer may be deposited on the surface of the IMD layer, and the embedded copper pad may be connected (e.g., by a metal filled TSV) to a metal level of the redistribution layer in the ASIC die. Method 500 may further include planarizing (e.g., by CMP) the second oxide layer including the second copper pad on the IMD layer.

Method 500 further includes bonding the first silicon wafer to the ASIC wafer to form a bonded assembly of the first silicon wafer and the ASIC wafer (513). Bonding the first silicon wafer to the ASIC wafer may include orienting the first silicon wafer so that the first oxide layer on the back surface of the first silicon wafer is face-to face with the second oxide layer on the ASIC wafer. The oxide layers (e.g., the first oxide layer and the second oxide layer) on the two wafers may be in mutual contact and the copper pads (the first copper pad and the second copper pad) on the two wafers may be aligned and fused with each other in a hybrid bonding process (including, e.g., oxide-oxide and metal-metal bonding).

In example implementations, when the first silicon wafer undergoes back grinding to expose an end of the metal filled TSV on the back surface of the first silicon substrate, the first silicon wafer may be mounted top surface down on a wafer carrier or support. The wafer carrier or support may be another silicon wafer, a glass plate, a ceramic plate, or a metal plate, etc. The wafer carrier or support may persist through the bonding step (of the first silicon wafer to the ASIC wafer) and may be removed after the bonding step to recover a bonded assembly of the first silicon wafer and the ASIC wafer.

In example implementations, method 500 may further include forming at least one metal electrode on a top surface of the first silicon wafer in the bonded assembly of the first silicon wafer and the ASIC wafer (514), and forming a metal-filled via to connect the at least one metal electrode to a metal level in the IMD layer of the first silicon wafer (515). The at least one metal electrode may be, for example, Ta/Cu electrodes and the metal-filled via may be, for example, Ta/Cu-filled vias. The at least one electrode may form a pixel electrode of a pixel capacitor in the final imager produced by method 500.

Each of the Ta/Cu electrodes may correspond to a SWIR-sensitive pixel in the CQD sensor assembly produced by method 500.

In some example implementations, method 500 may alternatively include forming Ti/W filled vias to individually connect the Ta/Cu electrodes to a polysilicon gate or a source region or a drain region of a device formed in the first silicon wafer.

Method 500 may further include depositing a layer of colloidal quantum dots (CQD) on the top surface of the first silicon wafer over the pattern of metal electrodes (516) and depositing a top electrode on the layer of colloidal quantum dots (517). The top electrode may be, for example, an ITO layer with ZnO and Al doping.

Method 500 may further include patterning and etching the layer of colloidal quantum dots and the top electrode to correspond to an array of SWIR sensitive pixels (518). Each pixel can include a CQD capacitor with a pair of capacitor plates formed by the at least one metal electrode and top electrode, and the CQD layer as the capacitive material.

In example implementations, method 500 may further include depositing an overlayer of silicon dioxide or other dielectric to passivate the assembly.

In example implementations, method 500 may further include forming a via to connect the top electrode to a metal level in the first silicon wafer. The top electrode may be connected, for example, to the M1 metal level in the IMD layer of the first silicon wafer.

Method 500 may further include planarization and deposition of an array of micro lenses on top of the assembly. Each micro lens may be configured to funnel incident light into a SWIR-sensitive pixel. In example implementations, the array of micro lenses may be made of organic or inorganic material (e.g., IR transparent, or colorless resists). The layer of micro lenses may include gapless micro lenses or pincushion micro lenses disposed above the pixel array.

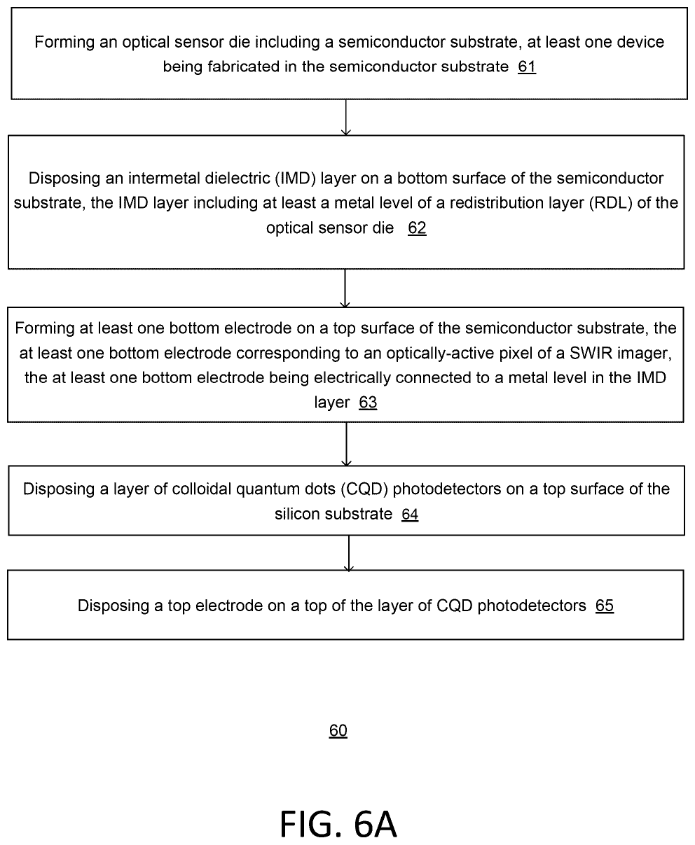

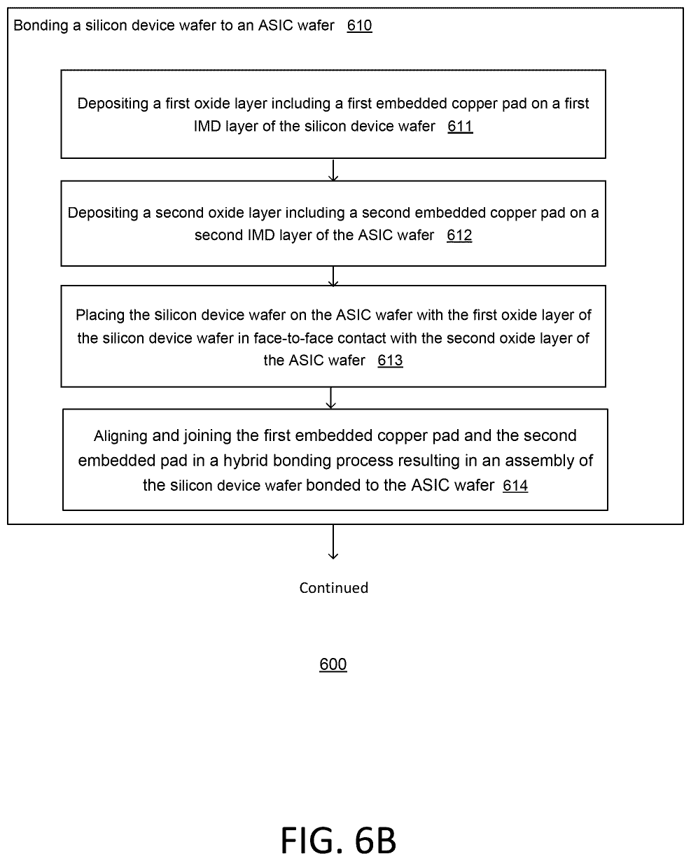

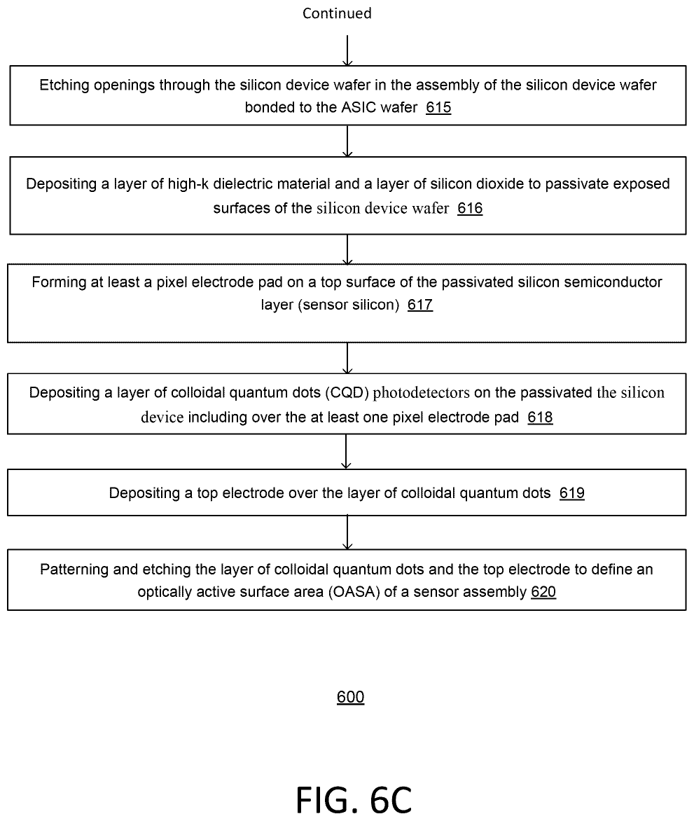

FIG. 6A shows an example method 60 for fabricating an example CQD imager (sensor assembly) configured for SWIR imaging under back side illumination (BSI) of the CQD sensor assembly.

Method 60 includes forming an optical sensor die including a semiconductor substrate (61). At least one device is fabricated in the semiconductor substrate. The at least one device may be, for example, a MOSFET device (e.g., an amplifier). Method 60 further includes disposing an intermetal dielectric (IMD) layer the semiconductor substrate (62). The IMD layer includes at least a metal level of a redistribution layer (RDL) of the optical sensor die. Method 60 further includes forming at least one bottom electrode on the semiconductor substrate (63). The at least one bottom electrode corresponds to an optically-active pixel of a SWIR imager. The least one bottom electrode is electrically connected to a metal level in the IMD layer. Method 50 further includes disposing a layer of colloidal quantum dots (CQD) photodetectors on the semiconductor substrate (64) including over the at least one bottom electrode, and disposing a top electrode on a top of the layer of CQD photodetectors (65).

In example implementations, each of an array of bottom electrodes may correspond to an optically-active pixel of a SWIR imager.

In example implementations, method 60 may include patterning and etching the layer of colloidal quantum dots and the top electrode to correspond to an array of short-wavelength infrared (SWIR) sensitive pixels.

In example implementations, method 60 may further include depositing an array of micro lenses on the semiconductor substrate. Each micro lens may be configured to funnel or focus incident light into a SWIR-sensitive pixel.

In some example implementations, the semiconductor substrate may be bonded to, and electrically connected to, an ASIC die. Bonding the semiconductor substrate to the ASIC die may involve depositing an oxide layer on the back surface of the semiconductor substrate and an oxide layer on an IMD layer of the ASIC die. The two oxide layers may include respective copper pads that are electrically connected to metal levels in respective redistribution layers of the optical sensor die and the ASIC die. In a bonding process, the oxide layer on the semiconductor substrate is placed in face-to-face contact with the oxide layer on the IMD layer of the ASIC die. The copper pads in the two oxide layers are mutually aligned and fused with each other in a hybrid bonding process (including, e.g., oxide-oxide and metal-metal bonding).

FIG. 6B and FIG. 6C show a first part and a second part, respectively, of an example method 600 for assembling an example CQD imager (sensor assembly) that includes an ASIC die configured for SWIR imaging under back side illumination (BSI) of the CQD sensor assembly.

As shown in FIG. 6B, the first part of method 600 for assembling the example CQD sensor assembly may include bonding a silicon device wafer to an ASIC wafer (610). The silicon device wafer (e.g., a 200 mm or a 300 mm diameter silicon wafer) may include a silicon semiconductor layer (sensor silicon) and a first IMD layer including different metal levels of a redistribution layer. A passivation layer may be disposed between the silicon semiconductor layer (sensor silicon) and the first IMD layer. The ASIC wafer may include an ASIC layer fabricated on or in a silicon substrate, and a second IMD layer including different metal levels of a redistribution layer disposed on the ASIC layer. A passivation layer may be disposed between the ASIC layer and the second IMD layer.

In example implementations, the silicon device wafer may be a p-doped silicon wafer.

Bonding the silicon device wafer to the ASIC wafer 610 may include depositing a first oxide layer including a first embedded copper pad on the first IMD layer of the silicon device wafer (611) and depositing a second oxide layer including a second embedded copper pad on the second IMD layer of the ASIC wafer (612).

Bonding the silicon device wafer to the ASIC wafer 610 may further involve placing the silicon device wafer on the ASIC wafer with the first oxide layer of the silicon device wafer in face-to-face contact with the second oxide layer of the ASIC wafer (613). This may involve flipping the silicon device wafer (e.g., upside down) so that the first oxide layer of the silicon device wafer is in face-to-face contact with the second oxide layer of the ASIC wafer. Bonding the silicon device wafer to the ASIC wafer 610 may further involve aligning and joining (e.g., fusing) the first embedded copper pad and the second embedded pad in a hybrid bonding process resulting in an assembly of the silicon device wafer bonded (and electrically connected) to the ASIC wafer (614).

In example implementations, method 600 may further involve thinning the silicon device wafer in the assembly of the silicon device wafer bonded to the ASIC wafer.

Thinning the silicon device wafer in the assembly of the silicon device wafer bonded to the ASIC wafer may, for example, involve coarse and fine grinding, wet etching, and chemical-mechanical polishing (CMP) processes.

As shown in FIG. 6C, the second part of method 600 involves incorporating CQD capacitor structures in the assembly of the silicon device wafer bonded to the ASIC wafer.

In some example implementations, as shown in FIG. 6C, method 600 may further involve etching openings through the silicon device wafer in the assembly of the silicon device wafer bonded to the ASIC wafer (step 615). The openings may be, for example, cavities (e.g., rectangular cavities) that extend through the thickness of the silicon device wafer to the underlying first IMD layer. The openings can be used later in method 600 to accommodate metal-filled vias, plugs or other connectors between CQD pixel electrodes and a metal level in the underlying first IMD layer.

Method 600 may further include depositing a layer of high-k dielectric material and a layer of silicon dioxide (SiO₂) to passivate exposed surfaces of the silicon device wafer (616). The exposed surfaces of the silicon device wafer may include top surfaces of an unetched silicon layer in the silicon device wafer, and the sidewalls of the openings that may be etched in the silicon layer at preceding method step 615. The high-k dielectric may be, for example, a combination of aluminum oxide, hafnium oxide and tantalum oxide (e.g., Al₂O₃+HfO₂+Ta₂O₅). Depositing the layer of silicon dioxide (SiO₂) may include depositing SiO₂ on the layer of high-k dielectric material and filling the openings with SiO₂.

Method 600 may further include forming at least one pixel electrode pad on a top surface of the passivated silicon device wafer (step 617). The pixel electrode pads may be, for example, a pattern of Ta/TiN/W pads. The at least one pixel electrode pad may correspond to a SWIR-sensitive pixel in the CQD sensor assembly produced by method 600.

In some example implementations, forming the at least one pixel electrode pad (step 617) may include connecting the at least one pixel electrode pad to a corresponding metal level in the IMD layer of the underlying the silicon device wafer. In example implementations, connecting the at least one pixel electrode pad to the metal level in the IMD layer, may include forming a metal-filled via or a metal plug extending from the pixel electrode pad through the openings (e.g., oxide-filled openings) in the silicon device wafer to the corresponding metal level (e.g., level M1) in the underlying IMD layer.

In some example implementations, forming the at least one pixel electrode pad (step 617) may include connecting the at least one pixel electrode pad to a polysilicon gate pad of a device in the silicon device wafer. In example implementations, connecting the at least one pixel electrode pad to the polysilicon gate pad, may include forming a metal-filled via or a metal plug extending from the pixel electrode pad through a thickness of the silicon device wafer to the polysilicon gate pad. The metal-filled via or metal plug may be, for example, made of titanium and tungsten (Ti/W).

In some example implementations, forming the at least one pixel electrode pad (step 617) may include connecting the at least one pixel electrode pad to a n+ source or n+ drain of a device formed in the silicon semiconductor layer (sensor silicon). In example implementations, connecting the at least one pixel electrode pad to the n+ source or n+ drain of the device may include forming a metal-filled via or a metal plug extending from the pixel electrode pad through the silicon semiconductor layer (sensor silicon) to the n+ source or n+ drain of the device. The metal-filled via or metal plug may be, for example, made of titanium and tungsten (Ti/W).

In example implementations, a via (for the metal filled-via or metal plug) may be etched through the silicon device wafer using a selective silicon etch with an etch stop on the polysilicon or on the n+ source or n+ drain.

Method 600 may further include depositing a layer of colloidal quantum dots (CQD) photodetectors on the passivated silicon device wafer including over the at least one pixel electrode pad (618), and depositing a top electrode over the layer of colloidal quantum dots (619). The top electrode may be, for example, made of transparent material (e.g., indium tin oxide (ITO) with aluminum (Al) doped zinc oxide (ZnO)).

Method 600 may further include patterning and etching the layer of CQD and the top electrode on the passivated sensor silicon to define an optically active surface area (OASA) of the sensor assembly (620). The OASA may overlay or include an array of optically active pixels (e.g., SWIR-sensitive pixels).

Method 600 may further include depositing a layer of a dielectric material over the top electrode to passivate the assembly. The layer of dielectric material may be, for example, a layer of silicon dioxide (e.g., SiO₂).

Method 600 may further include forming a metal-filled via through the dielectric layer and the silicon semiconductor layer (sensor silicon) to make a connection between the top electrode and a metal level in the IMD layer. The metal-filled via may, for example, connect the top electrode to the metal level M1 in the underlying IMD layer.

Method 600 may further include planarization and deposition of an array of micro lenses on top of the assembly. Each of the micro lenses may be configured to funnel incident light (e.g., SWIR and/or IR light) into a SWIR-sensitive pixel. In example implementations, the array of micro lenses may be made of organic or inorganic material (e.g., IR transparent, or colorless resists). The layer of micro lenses may include gapless micro lenses or pincushion micro lenses disposed above the pixel array.

In example implementation, method 600 may further include making an opening through the sensor silicon and the IMD to expose a wire bond pad (e.g., an aluminum pad) disposed in the IMD. The aluminum pad may be used, for example, for wire bonding an external wire connection to the back side of the CQD sensor assembly configured for SWIR imaging under back side illumination (BSI).

In example implementations, method 600 may include forming an in-pixel trench capacitor between the at least one bottom electrode and the semiconductor substrate with the high-k dielectric material disposed on a top surface of the semiconductor substrate and in the opening in the semiconductor substrate forming a capacitive material of the in-pixel trench capacitor.

In example implementations, the method includes disposing a layer of passivating material including at least one of high-k dielectric material and silicon dioxide on a top surface of the semiconductor substrate and in an opening in the semiconductor substrate and wherein forming at least one bottom electrode on the semiconductor substrate corresponding to an optically-active pixel of a SWIR imager includes forming a high-k dielectric material capacitor between the at least one bottom electrode and the semiconductor substrate, wherein the high-k dielectric material capacitor is formed as an in-pixel trench capacitor.

Clause 1. An imager configured for capturing short-wavelength infrared (SWIR) images (100), the imager comprising: an optical sensor die (210) including a semiconductor substrate (212), at least one device (246) fabricated in the semiconductor substrate; an intermetal dielectric (IMD) layer (213) disposed on the semiconductor substrate, the IMD layer including at least a metal level (M1-M4) of a redistribution layer (RDL) (213M) of the optical sensor die; and a layer of colloidal quantum dots (CQD) photodetectors (240) disposed on the IMD layer.

Clause 2. The imager of clause 1 further comprising: a top electrode disposed on the layer of CQD photodetectors; and an array of bottom electrodes disposed on a top surface of the IMD layer underneath the layer of CQD photodetectors, each of the array of bottom electrodes corresponding to an optically-active pixel of the imager. Clause 3. The imager of clause 2, wherein the optically-active pixel of the imager includes a capacitor with a pair of capacitor plates formed by one of the array of bottom electrodes and the top electrode, and the CQD layer forms a capacitive material of the capacitor. Clause 4. The imager of clause 2, wherein at least one of the array of bottom electrodes is electrically connected to a metal level in the IMD layer by a metal-filled via extending through the IMD layer. Clause 5. The imager of clause 2, wherein at least one of the array of bottom electrodes is electrically connected one of a polysilicon gate or a doped source region of a transistor formed in or on the semiconductor substrate by a metal-filled via extending through the IMD layer. Clause 6. The imager of clause 1, wherein the semiconductor substrate is a first semiconductor substrate, the redistribution layer is a first redistribution layer, and the IMD layer is a first IMD layer, the imager further comprising: an application specific integrated circuit (ASIC) die including a second semiconductor substrate; and a second IMD layer disposed on the second semiconductor substrate, the second IMD layer including at least a metal level of a second redistribution layer (RDL) of the ASIC die, wherein the optical sensor die is stacked above the ASIC die with a dielectric layer disposed between the first semiconductor substrate and the second IMD layer, the dielectric layer bonding the optical sensor die to the ASIC die. Clause 7. The imager of clause 6, wherein the dielectric layer disposed between the first semiconductor substrate and the second IMD layer includes a pair of copper pads that are fused together to electrically connect the first redistribution layer (RDL) of the optical sensor die and the second redistribution layer (RDL) of the ASIC die. Clause 8. The imager of clause 1, wherein the layer of colloidal quantum dots (CQD) includes colloidal semiconductor nanocrystals dispersed in a film. Clause 9. The imager of clause 8, wherein colloidal semiconductor nanocrystals include, at least one of PbS, InAs, InP, PbSe, CdS, CdSe, InxGa1-xAs, CdHgTe, ZnSe (PbS), ZnS (CdSe), ZnSe (CdS), PbO (PbS), and PbSO4 (PbS). Clause 10. The imager of clause 1 further comprising: an array of micro lenses disposed above the layer of CQD photodetectors to funnel incident infrared (IR) or short-wavelength infrared (SWIR) light into an optically-active pixel.

Clause 11. An imager (300) configured for capturing short-wavelength infrared (SWIR) images, the imager comprising: an optical sensor die (310) including a semiconductor substrate (312), at least one device (346) fabricated in the semiconductor substrate; a layer of colloidal quantum dots (CQD) photodetectors (340) disposed above the semiconductor substrate; and an intermetal dielectric (IMD) layer (313) disposed on a bottom surface of the semiconductor substrate, the IMD layer including at least a metal level (M1-M4) of a redistribution layer (RDL) (313M) of the optical sensor die.

Clause 12. The imager of clause 11, further comprising: a layer of passivating material disposed on the top surface of the semiconductor substrate underneath the layer of CQD photodetectors, the layer of passivating material including at least one of silicon dioxide and a high-k dielectric material. Clause 13. The imager of clause 11, further comprising: a top electrode disposed on the layer of CQD photodetectors; and an array of bottom electrodes disposed on the semiconductor substrate underneath the layer of CQD photodetectors, each of the array of bottom electrodes corresponding to an optically-active pixel of the imager. Clause 14. The imager of clause 13, wherein at least one of the array of bottom electrodes is electrically connected to a metal level in the IMD layer by a metal-filled via extending through the semiconductor substrate. Clause 15. The imager of clause 13, wherein at least one of the array of bottom electrodes is electrically connected to one of a polysilicon gate or a doped source region of a transistor formed in or on the semiconductor substrate by a metal-filled via extending through the semiconductor substrate. Clause 16. The imager of clause 11, wherein the semiconductor substrate is a first semiconductor substrate, the redistribution layer is a first redistribution layer, and the IMD layer is a first IMD layer, the imager further comprising: an application specific integrated circuit (ASIC) die including a second semiconductor substrate; and a second IMD layer disposed on the second semiconductor substrate, the second IMD layer including at least a metal level of a second redistribution layer (RDL) of the ASIC die, wherein the optical sensor die is stacked above the ASIC die with a dielectric layer disposed between the bottom surface of first semiconductor substrate and a top surface of the second IMD layer, the dielectric layer bonding the optical sensor die to the ASIC die. Clause 17. The imager of clause 16, wherein the dielectric layer disposed between the bottom surface of first semiconductor substrate and the top surface of the second IMD layer includes a pair of copper pads that are fused together to electrically connect the first RDL of the optical sensor die and the second RDL of the ASIC die. Clause 18. The imager of clause 11, wherein the layer of CQD includes colloidal semiconductor nanocrystals dispersed in a film. Clause 19. The imager of clause 18, wherein colloidal semiconductor nanocrystals include at least one of PbS, InAs, InP, PbSe, CdS, CdSe, InxGa1-xAs, CdHgTe, ZnSe (PbS), ZnS (CdSe), ZnSe (CdS), PbO (PbS), and PbSO4 (PbS). Clause 20. The imager of clause 19 further comprising: an array of micro lenses configured to funnel incident infrared (IR) or SWIR light into an optically-active pixel of the imager.

Clause 21. A method, comprising: forming an optical sensor die including a semiconductor substrate, at least one device being fabricated in the semiconductor substrate (51); disposing an intermetal dielectric (IMD) layer on the semiconductor substrate, the IMD layer including at least a metal level of a redistribution layer (RDL) of the optical sensor die (52); forming at least one bottom electrode on the semiconductor substrate, the at least one bottom electrode corresponding to an optically-active pixel of a SWIR imager, the at least one bottom electrode being electrically connected to a metal level in the IMD layer (53); disposing a layer of colloidal quantum dots (CQD) photodetectors on the semiconductor substrate including over the at least one bottom electrode (54); and disposing a top electrode on the layer of CQD photodetectors (55).

Clause 22. The method of clause 21, further comprising: coating a top surface of the semiconductor substrate with a layer of high-k dielectrics. Clause 23. The method of clause 21, further comprising: bonding and electrically connecting the semiconductor substrate to an ASIC die. Clause 24. The method of clause 21, further comprising: patterning and etching the layer of colloidal quantum dots and the top electrode to correspond to an array of short-wavelength infrared (SWIR) sensitive pixels.

Clause 25. A method, comprising: forming an optical sensor die including a semiconductor substrate, at least one device being fabricated in the semiconductor substrate (61); disposing a intermetal dielectric (IMD) layer on the semiconductor substrate, the IMD layer including at least a metal level of a redistribution layer (RDL) of the optical sensor die (62); forming at least one bottom electrode on the IMD layer, the at least one bottom electrode corresponding to an optically-active pixel of a SWIR imager, the at least one bottom electrode being electrically connected to a metal level in the IMD layer (63); disposing a layer of colloidal quantum dots (CQD) photodetectors on the IMD layer including over the at least one bottom electrode (64); and disposing a top electrode on the layer of CQD photodetectors (65).

Clause 26. The method of clause 25, further comprising: patterning and etching the layer of colloidal quantum dots and the top electrode to correspond to an array of short-wavelength infrared (SWIR) sensitive pixels. Clause 27. The method of clause 25, further comprising: bonding and electrically connecting the semiconductor substrate to an ASIC die. Clause 28. The method of clause 25, further comprising: depositing of an array of micro lenses on the semiconductor substrate.

While certain features of the described implementations have been illustrated as described herein, many modifications, substitutions, changes, and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

It will be understood that, in the foregoing description, when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Unless defined otherwise, all technical and scientific terms used herein have the same meaning as commonly understood by one of ordinary skill in the art. Methods and materials similar or equivalent to those described herein can be used in the practice or testing of the present disclosure. As used in the specification, and in the appended claims, the singular forms “a,” “an,” “the” include plural referents unless the context clearly dictates otherwise. The term “comprising,” and variations thereof as used herein is used synonymously with the term “including” and variations thereof and are open, non-limiting terms. The terms “optional” or “optionally” used herein mean that the subsequently described feature, event or circumstance may or may not occur, and that the description includes instances where said feature, event or circumstance occurs and instances where it does not. Ranges may be expressed herein as from “about” one particular value, and/or to “about” another particular value. When such a range is expressed, an aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Some implementations may be implemented using various semiconductor processing techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

What is claimed is:

1. An imager configured for capturing short-wavelength infrared images, the imager comprising:
an optical sensor die including a semiconductor substrate, at least one device fabricated in the semiconductor substrate;
an intermetal dielectric layer disposed on the semiconductor substrate, the intermetal dielectric layer including at least a metal level of a redistribution layer of the optical sensor die; and
a layer of colloidal quantum dot photodetectors disposed on the intermetal dielectric layer.

2. The imager of claim 1 further comprising:
a top electrode disposed on the layer of colloidal quantum dot photodetectors; and
an array of bottom electrodes disposed on a top surface of the intermetal dielectric layer underneath the layer of colloidal quantum dot photodetectors, each of the array of bottom electrodes corresponding to an optically-active pixel of the imager.

3. The imager of claim 2, wherein the optically-active pixel of the imager includes a capacitor with a pair of capacitor plates formed by one of the array of bottom electrodes and the top electrode, and the layer of colloidal quantum dot photodetectors forms a capacitive material of the capacitor.

4. The imager of claim 2, wherein at least one of the array of bottom electrodes is electrically connected to a metal level in the intermetal dielectric layer by a metal-filled via extending through the intermetal dielectric layer.

5. The imager of claim 2, wherein at least one of the array of bottom electrodes is electrically connected one of a polysilicon gate or a doped source region of a transistor formed in or on the semiconductor substrate by a metal-filled via extending through the intermetal dielectric layer.

6. The imager of claim 1, wherein the semiconductor substrate is a first semiconductor substrate, the redistribution layer is a first redistribution layer, and the intermetal dielectric layer is a first intermetal dielectric layer, the imager further comprising:
an application specific integrated circuit die including a second semiconductor substrate; and
a second intermetal dielectric layer disposed on the second semiconductor substrate, the second intermetal dielectric layer including at least a metal level of a second redistribution layer of the application specific integrated circuit die,
wherein the optical sensor die is stacked above the application specific integrated circuit die with a dielectric layer disposed between the first semiconductor substrate and the second intermetal dielectric layer, the dielectric layer bonding the optical sensor die to the application specific integrated circuit die.

7. The imager of claim 6, wherein the dielectric layer disposed between the first semiconductor substrate and the second intermetal dielectric layer includes a pair of copper pads that are fused together to electrically connect the first redistribution layer of the optical sensor die and the second redistribution layer of the application specific integrated circuit die.

8. The imager of claim 1, wherein the layer of colloidal quantum dots includes colloidal semiconductor nanocrystals dispersed in a film.

9. The imager of claim 8, wherein colloidal semiconductor nanocrystals include, at least one of PbS, InAs, InP, PbSe, CdS, CdSe, InₓGa₁₋ₓAs, CdHgTe, ZnSe (PbS), ZnS (CdSe), ZnSe (CdS), PbO (PbS), and PbSO₄ (PbS).

10. The imager of claim 1 further comprising:
an array of micro lenses disposed above the layer of colloidal quantum dot photodetectors to funnel incident infrared or short-wavelength infrared light into an optically-active pixel.

11. The imager of claim 2, wherein a high-k dielectric material is disposed on the top surface of the semiconductor substrate, and wherein the optically-active pixel of the imager includes a capacitor with a pair of capacitor plates formed by one of the array of bottom electrodes and the semiconductor substrate, and the high-k dielectric material forms a capacitive material of the capacitor.

12. The imager of claim 11, wherein the top surface of the semiconductor substrate includes a sidewall of an opening etched in the semiconductor substrate, wherein a portion of the layer of passivating material is disposed on the sidewall of the opening, and wherein the capacitor is formed as an in-pixel trench capacitor.

13. The imager of claim 11, further comprising:
a layer of passivating material disposed on a top surface of the semiconductor substrate underneath the layer of colloidal quantum dot photodetectors, the layer of passivating material including silicon oxide and a high-k dielectric material; and
an array of bottom electrodes disposed on the semiconductor substrate underneath the layer of colloidal quantum dot photodetectors, each of the array of bottom electrodes corresponding to an optically-active pixel of the imager, each of the array of bottom electrodes forming a high-k dielectric material capacitor with the semiconductor substrate being an opposing electrode of the high-k dielectric material capacitor and the high-k dielectric material forming a capacitive material of the high-k dielectric material capacitor.

14. The imager of claim 13, wherein the top surface of the semiconductor substrate includes a sidewall of an opening etched in the semiconductor substrate, wherein portions of the layer of passivating material are disposed on the sidewall of the opening, and wherein the high-k dielectric material capacitor is formed as an in-pixel trench capacitor.

15. An imager configured for capturing short-wavelength infrared short- wavelength infrared images, the imager comprising:
an optical sensor die including a semiconductor substrate, at least one device fabricated in the semiconductor substrate;
a layer of colloidal quantum dot photodetectors disposed above the semiconductor substrate; and
an intermetal dielectric layer disposed on a bottom surface of the semiconductor substrate, the intermetal dielectric layer including at least a metal level of a redistribution layer of the optical sensor die.

16. The imager of claim 15, further comprising:
a layer of passivating material disposed on a top surface of the semiconductor substrate underneath the layer of colloidal quantum dot photodetectors, the layer of passivating material including at least one of silicon dioxide and a high-k dielectric material.

17. The imager of claim 15, further comprising:
a top electrode disposed on the layer of colloidal quantum dot photodetectors; and
an array of bottom electrodes disposed on the semiconductor substrate underneath the layer of colloidal quantum dot photodetectors, each of the array of bottom electrodes corresponding to an optically-active pixel of the imager.

18. The imager of claim 17, wherein at least one of the array of bottom electrodes is electrically connected to a metal level in the intermetal dielectric layer by a metal-filled via extending through the semiconductor substrate.

19. The imager of claim 17, wherein at least one of the array of bottom electrodes is electrically connected to one of a polysilicon gate or a doped source region of a transistor formed in or on the semiconductor substrate by a metal-filled via extending through the semiconductor substrate.

20. The imager of claim 15, wherein the semiconductor substrate is a first semiconductor substrate, the redistribution layer is a first redistribution layer, and the intermetal dielectric layer is a first intermetal dielectric layer, the imager further comprising:
an application specific integrated circuit die including a second semiconductor substrate; and
a second intermetal dielectric layer disposed on the second semiconductor substrate, the second intermetal dielectric layer including at least a metal level of a second redistribution layer of the application specific integrated circuit die,
wherein the optical sensor die is stacked above the application specific integrated circuit die with a dielectric layer disposed between the bottom surface of first semiconductor substrate and a top surface of the second intermetal dielectric layer, the dielectric layer bonding the optical sensor die to the application specific integrated circuit die.

21. The imager of claim 20, wherein the dielectric layer disposed between the bottom surface of first semiconductor substrate and the top surface of the second intermetal dielectric layer includes a pair of copper pads that are fused together to electrically connect the first redistribution layer of the optical sensor die and the second redistribution layer of the application specific integrated circuit die.

22. A method, comprising:
forming an optical sensor die including a semiconductor substrate, at least one device being fabricated in the semiconductor substrate;
disposing an intermetal dielectric layer on the semiconductor substrate, the intermetal dielectric layer including at least a metal level of a redistribution layer of the optical sensor die;
forming at least one bottom electrode on the semiconductor substrate, the at least one bottom electrode corresponding to an optically-active pixel of a short-wavelength infrared imager, the at least one bottom electrode being electrically connected to a metal level in the intermetal dielectric layer;
disposing a layer of colloidal quantum dot photodetectors on the semiconductor substrate including over the at least one bottom electrode; and
disposing a top electrode on the layer of colloidal quantum dot photodetectors.

23. The method of claim 22, further comprising:
patterning and etching the layer of colloidal quantum dots and the top electrode to correspond to an array of short-wavelength infrared sensitive pixels.

24. The method of claim 22, further comprising:
disposing a layer of passivating material including at least one of high-k dielectric material and silicon dioxide on a top surface of the semiconductor substrate and in an opening in the semiconductor substrate.

25. The method of claim 24, further comprising:
forming an in-pixel trench capacitor between the at least one bottom electrode and the semiconductor substrate with the high-k dielectric material disposed on a top surface of the semiconductor substrate and in the opening in the semiconductor substrate forming a capacitive material of the in-pixel trench capacitor.

26. The method of claim 25, further comprising:
disposing a layer of passivating material including at least one of high-k dielectric material and silicon dioxide on a top surface of the semiconductor substrate and in an opening in the semiconductor substrate and wherein forming at least one bottom electrode on the semiconductor substrate corresponding to an optically-active pixel of a short-wavelength infrared imager includes forming a high-k dielectric material capacitor between the at least one bottom electrode and the semiconductor substrate, wherein the high-k dielectric material capacitor is formed as an in-pixel trench capacitor.

27. A method, comprising:
forming an optical sensor die including a semiconductor substrate, at least one device being fabricated in the semiconductor substrate;
disposing an intermetal dielectric layer on the semiconductor substrate, the intermetal dielectric layer including at least a metal level of a redistribution layer of the optical sensor die;
forming at least one bottom electrode on the intermetal dielectric layer, the at least one bottom electrode corresponding to an optically-active pixel of a short-wavelength infrared imager, the at least one bottom electrode being electrically connected to a metal level in the intermetal dielectric layer;
disposing a layer of colloidal quantum dot photodetectors on the intermetal dielectric layer including over the at least one bottom electrode; and
disposing a top electrode on the layer of colloidal quantum dot photodetectors.

28. The method of claim 27, further comprising:
patterning and etching the layer of colloidal quantum dots and the top electrode to correspond to an array of short-wavelength infrared sensitive pixels.
